(19) United States
(12) Patent Application Publication
(10) Pub. No.: US 2005/0009209 A1
(43) Pub. Date: Jan. 13, 2005

(54) Process for selectively sealing ferroelectric capactive elements incorporated in semiconductor integrated non-volatile memory cells

(75) Inventor: Raffaele Zambrano, Viagrande (IT)

Correspondence Address: SEED INTELLECTUAL PROPERTY LAW GROUP PLLC, 701 FIFTH AVE, SUITE 6300, SEATTLE, WA, 98104-7092, US

(73) Assignee: STMicroelectronics S.r.l., Agrate Brianza (IT)

(21) Appl. No.: 10/447,209

(22) Filed: May 27, 2003

Related U.S. Application Data
(63) Continuation-in-part of application No. 09/710,066, filed on Nov. 9, 2000, now Pat. No. 6,579,727.

(30) Foreign Application Priority Data
Nov. 10, 1999 (IT) MI99A002350

(51) Int. Cl. H01L 21/00

(52) U.S. Cl. 438/3

(57) ABSTRACT

A process for selectively sealing a capacitive element incorporated in a non-volatile memory cell integrated in a semiconductor substrate, the cell including a MOS transistor. The process includes: forming the MOS transistor on the semiconductor substrate; depositing an insulating layer over the substrate and MOS transistor; depositing a first metal layer to form, using a photolithographic technique, a lower electrode of the capacitive element; depositing a dielectric layer onto the first metal layer; depositing a second metal layer onto the dielectric layer; depositing a layer of a sealing material onto the second metal layer, the sealing material being impermeable to hydrogen; and defining the dielectric layer, second metal layer, and sealing layer by a single photolithographic defining step, so to form an upper electrode in the second metal layer and concurrently pattern the dielectric layer and seal the capacitive element.

### CROSS-REFERENCE TO RELATED APPLICATION

This application is a continuation-in-part of U.S. patent application Ser. No. 09/710,066, filed Nov. 9, 2000, now pending, which application is incorporated herein by reference in its entirety.

### BACKGROUND OF THE INVENTION

1. Field of the Invention

This invention relates to a process for selectively sealing ferroelectric capacitive elements incorporated in semiconductor integrated non-volatile memory cells.

The invention relates, particularly but not exclusively, to a process for fabricating ferroelectric capacitive elements of non-volatile memory cells of the ferroelectric type and stacked configuration, and the description to follow makes reference to this field of application for simplicity's sake only.

2. Description of the Related Art

As is well known, electronic semiconductor ferroelectric non-volatile memory devices comprise pluralities of ferroelectric non-volatile memory cells organized into a matrix array. This means that the cells would be laid in rows or wordlines, and columns or bitlines.

Each ferroelectric non-volatile memory cell comprises a MOS transistor and a ferroelectric capacitive element.

Conventional processes for making such memory cells comprise providing an insulating layer over the entire chip surface, after the MOS transistor has been integrated in a semiconductor substrate. The ferroelectric capacitive element is then formed on top of that insulating layer.

The capacitive element is conventionally provided with a metal lower electrode laid onto the insulating layer.

A layer of a ferroelectric material covers the lower electrode, and a metal upper electrode is laid onto the ferroelectric layer.

However, the presence of hydrogen during subsequent steps to the formation of the ferroelectric capacitive element may affect the ferroelectric material layer, causing its chemio-physical properties, and hence its electric characteristics, to deteriorate.

A prior approach to sealing the ferroelectric capacitive element provides for the use of an insulating layer which is impermeable to hydrogen in a selective way, that is, it is impermeable only in those regions which contain the capacitive element. In fact, hydrogen is a requisite if the electric characteristics of MOS transistors are to be stabilized.

While being in many ways an effective one, this prior approach involves a whole series of dedicated process steps.

### BRIEF SUMMARY OF THE INVENTION

An embodiment of this invention provides a process for selectively sealing ferroelectric capacitive elements with such features that the ferroelectric layer can be protected without introducing any additional process steps, thereby overcoming the limitations and drawbacks which still beset prior art processes.

The process selectively seals ferroelectric capacitive elements, wherein the dielectric layer and the sealing layer are defined in one process step.

Specifically, the process selectively seals ferroelectric capacitive elements incorporated in non-volatile memory cells being integrated in a semiconductor substrate and comprising at least one MOS transistor. The process includes the following steps: forming said at least one MOS transistor on the semiconductor substrate, depositing an insulating layer over the whole surface of the semiconductor, forming a ferroelectric layer between first and second metal electrodes, forming a sealing layer on the second metal electrode, and defining the sealing layer and ferroelectric layer using a photolithographic process.

The features and advantages of the process according to the invention will be apparent from the following description of an embodiment thereof, given by way of example and not of limitation with reference to the accompanying drawings.

### BRIEF DESCRIPTION OF THE SEVERAL VIEWS OF THE DRAWINGS

In the drawings:

FIGS. 1 to 4 are sectional views of certain portions of a semiconductor substrate where a plurality of ferroelectric memory cells, incorporating a capacitive element in accordance with the sealing process of this invention, have been formed.

FIG. 5 is sectional view of a ferroelectric memory cell, incorporating a capacitive element formed in accordance with a second embodiment of the sealing process of this invention.

### DETAILED DESCRIPTION OF THE INVENTION

With reference to the drawings, a process for sealing a ferroelectric capacitor in non-volatile memories, according to an embodiment of the invention, is as described herein below.

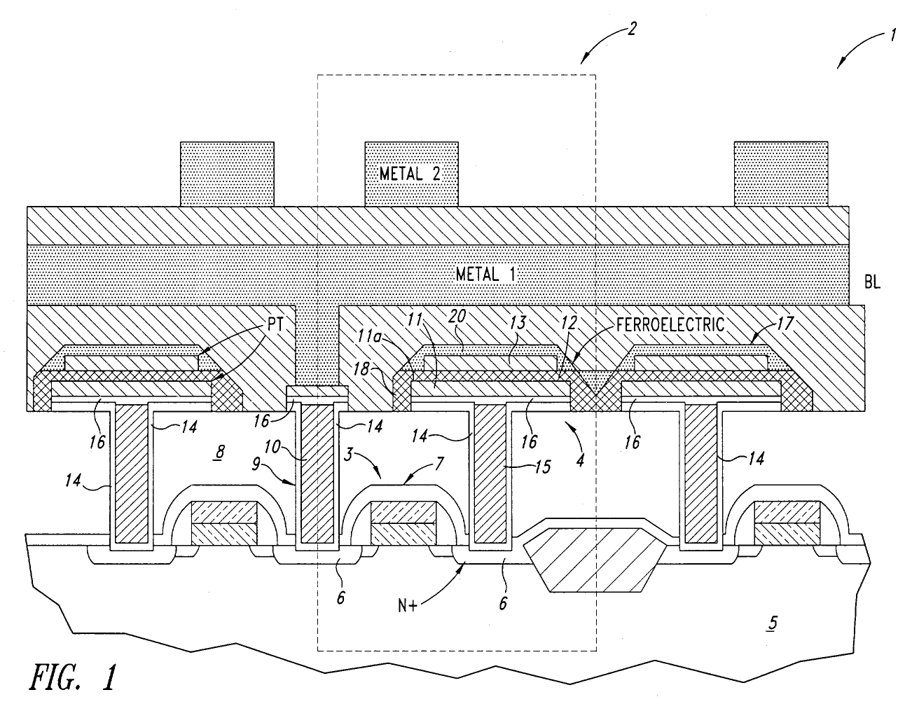

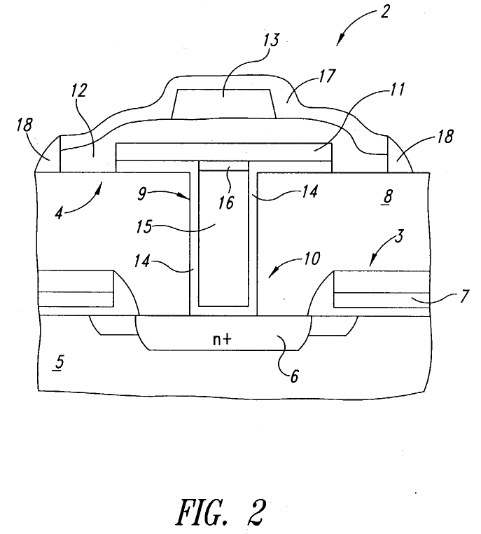

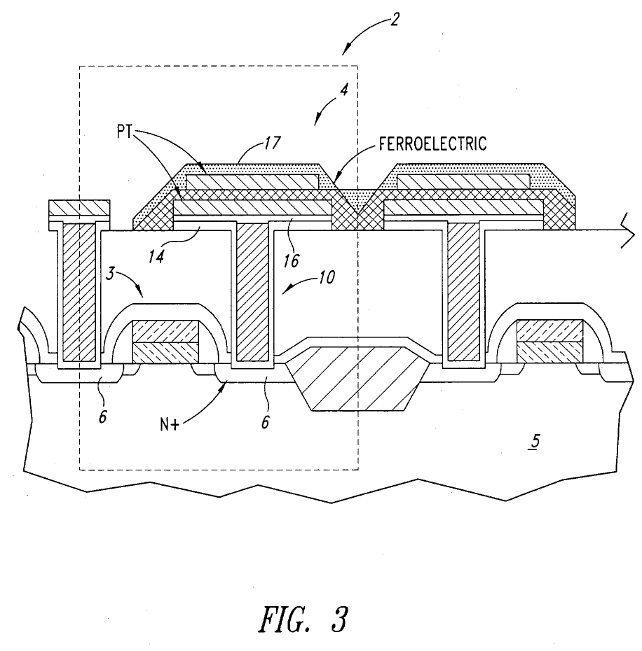

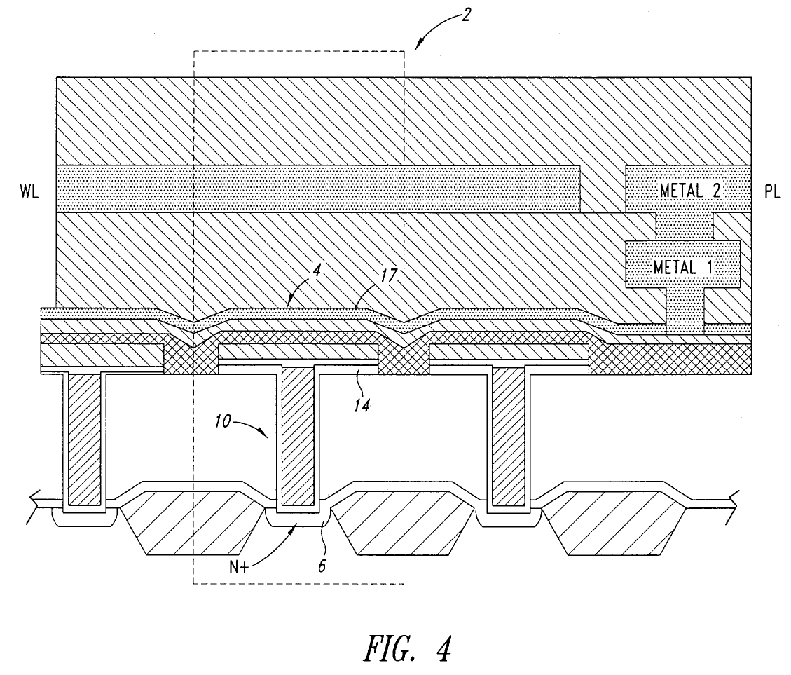

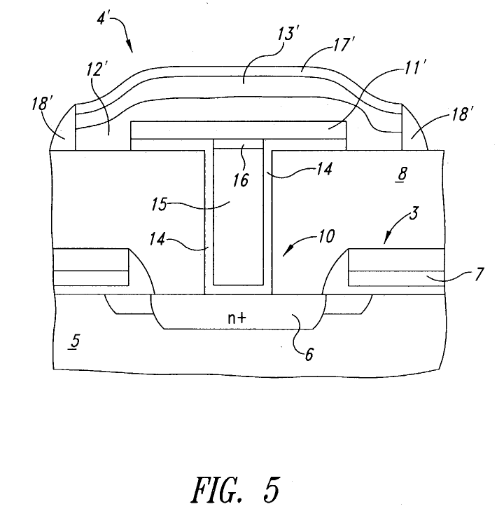

An electronic semiconductor memory device of the ferroelectric type comprises a plurality of non-volatile memory cells 2 organized into a matrix array 1, meaning that the cells are laid in rows or wordlines WL, and columns or bitlines BL, as shown in FIG. 1.

Each ferroelectric memory cell 2 comprises: a MOS transistor 3 connected in series with a ferroelectric capacitive element 4. Specifically, one end of the ferroelectric capacitive element is connected to a conduction terminal of the transistor 3.

The plurality of memory cells 2 are univocally identified by intersections of the bitlines and the wordlines.

Referring to the drawing views, a set of MOS transistors 3 are formed on the semiconductor substrate 5. Each MOS transistor 3 has first and second conduction terminals 6, 6A which are both formed in respective source and drain regions of the substrate.

A gate (control) electrode 7 of polysilicon overlies that region of the substrate which extends between pairs of the conduction terminals 6, and is isolated from the surface of the substrate 5 by a thin oxide layer.

In this embodiment, pairs of transistors 3 belonging to the same column BL have a conduction terminal in common.

An insulating layer 8, e.g., of a doped oxide with boron and phosphorus (BPSG), is subsequently laid over the entire semiconductor surface.

The insulating layer 8 may be a layer of non-reflowed and/or planarized oxide obtained by a conventional CMP (Chemical Mechanical Polishing) process.

Formed through the insulating layer at the locations of the conduction terminals 6, are respective openings 9 for conventionally providing respective contacts 10.

Advantageously, the ferroelectric capacitive elements 4 are formed at each MOS transistor 3.

In a specially advantageous embodiment, each contact 10 is coated with a thin barrier metal layer 14, e.g., of titanium or titanium nitride or combination thereof (Ti/TiN).

The metal layer 14 would also line the edges of the openings 9.

The contact 10, thus coated, is then filled with a filler 15, which may either be a dielectric material such as silicon oxide or a conducting material such as tungsten W. Advantageously, an additional barrier layer 16, e.g., of iridium oxide IrO₂, restricts the filler in the opening 9.

At this stage the ferroelectric capacitive elements 4 are formed.

A metal layer 11a, e.g., of platinum, is deposited over the entire surface of the wafer. Using a conventional photolithographic technique, a plurality of lower electrodes 11 are defined.

These lower electrodes 11 are formed at contacts 10 connected to the first conduction terminals 6.

A layer of a ferroelectric material 12, such as barium titanate, is deposited over the whole wafer surface.

This layer 12 serves a dielectric function between the plates of the capacitive element 4.

A second metal layer 13a, e.g., of platinum, is deposited over the whole surface of the wafer. A plurality of upper electrodes 13 are defined by a conventional photolithographic technique.

A layer of a sealing material 17 is then deposited over the whole surface of the semiconductor, including the ferroelectric layer 12 and upper electrodes 13. A mask (not shown) is then placed on the sealing layer 17 and then both the ferroelectric layer 12 and sealing layer 17 are etched in a single step through apertures in the mask.

Advantageously, this sealing layer 17 is a layer of a material impermeable to hydrogen, so as to protect the ferroelectric material layer 12 against subsequent processing based on the use of hydrogen, which could affect the layer characteristics adversely. The sealing layer 17 also preferably is a material susceptible of etching with the ferroelectric layer 12 selectively with respect to the upper electrodes 13. Examples of such materials for the sealing layer 17 include ferroelectric materials, aluminum oxide, and a combination layer that includes a layer of TEOS and a layer of silicon nitride.

Advantageously, the ferroelectric material layer 12 is defined to completely cover the lower electrode 11 of the capacitive element 4. The sealing layer 17, in turn, completely covers the upper electrode 13 and ferroelectric layer 12 of the capacitive element.

In a modified embodiment of the invention, dielectric spacers 18 may be formed at the sides of the capacitive element 4 to seal off the dielectric layer 12.

The process of making the ferroelectric capacitive element 4 and non-volatile memory cells is then completed in a manner known in the art, by depositing successive insulating and metallization layers (Metal 1 and Metal 2).

It is now described a modified embodiment of the invention. In this embodiment the steps of forming the transistor 3 are the same. After the formation of the insulating layer 8 and the contacts 10, ferroelectric capacitive elements 4′ are formed.

A metal layer 11a, e.g. of platinum, is deposited over the entire surface of the wafer. Using a conventional photolithographic technique, a plurality of lower electrodes 11 are defined.

These lower electrodes 11 are formed at contacts 10 and connected to the first conduction terminals 6.

According to this embodiment, a multilayer structure is deposited over the whole wafer surface: in particular a layer of a ferroelectric material 12′, a second metal layer 13b, e.g. of platinum and a layer of a sealing material 17′ are sequentially deposed.

The sealing layer 17′, the ferroelectric material layer 12′ and the second metal layer 13b are all defined by a conventional photolithographic technique to define, at the same time, the sealing layer 17′, the upper electrode 13′and the ferroelectric material layer 12′. In particular, this multilayer structure comprising layers 17′, 13′ and 12′ cover completely and extend laterally of the lower electrodes 11.

In another embodiment, spacers 18′ may be formed at the sides of the capacitive element 4 to seal off the dielectric layer 12′ and the upper electrode 13′.

Advantageously, spacers 18′ are formed by a dielectric layer.

In these last embodiments, the sealing layer 17′, the ferroelectric material layer 12′ and the second metal layer 13b have all the same properties as the corresponding layers of the previous embodiment.

Summarizing, the process described above allows a ferroelectric capacitive element to be advantageously sealed in a selective way, without adding any dedicated process steps to the standard process flow for fabricating semiconductor integrated circuits.

All of the above U.S. patents, U.S. patent application publications, U.S. patent applications, foreign patents, foreign patent applications and non-patent publications referred to in this specification and/or listed in the Application Data Sheet, are incorporated herein by reference in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A process for selectively sealing a capacitive element incorporated in a non-volatile memory cell integrated in a semiconductor substrate, the cell including a MOS transistor, the process comprising:
forming said MOS transistor on the semiconductor substrate;
depositing an insulating layer over the substrate and MOS transistor, depositing a first metal layer to form, using a photolithographic technique, a lower electrode of said capacitive element;
depositing a layer of a dielectric material onto said first metal layer;
depositing a second metal layer onto said layer of a dielectric material;
depositing a layer of a sealing material onto said second metal layer, the sealing material being impermeable to hydrogen; and
defining the dielectric material layer, the second metal layer, and the sealing layer by a single photolithographic defining step, so to form an upper electrode in said second metal layer and concurrently pattern said dielectric layer and seal said capacitive element.

2. The process of claim 1, wherein the dielectric layer is a layer of a ferroelectric material.

3. The process of claim 1, wherein the sealing material layer is a layer of a ferroelectric material.

4. The process of claim 1, wherein spacers are formed from a ferroelectric material.

5. The process of claim 1, wherein spacers are formed laterally of the capacitive element to seal the dielectric layer along its sides.

6. The process of claim 1, wherein the lower electrode is connected to a conduction terminal of said MOS transistor through a contact formed in an opening in the insulating layer, said contact comprising a metal layer lining the opening.

7. The process of claim 6, wherein the opening is filled with an insulating material.

8. The process of claim 6, wherein the opening is filled with a conducting material.

9. The process of claim 1 wherein the step of depositing the dielectric layer includes extending the dielectric layer beyond the lower electrode such that the dielectric layer contacts lateral sides of the lower electrode.

10. A process for selectively sealing a capacitive element incorporated: in a non-volatile memory cell integrated in a semiconductor substrate, the memory cell including a MOS transistor, the process comprising:
forming the MOS transistor on the semiconductor substrate;
depositing an insulating layer over the substrate and MOS transistor;
forming a conductive lower electrode of the capacitive element on the insulating layer;
depositing a dielectric layer onto the lower electrode;
forming a conductive upper electrode of the capacitive element on the dielectric layer;
forming on the upper electrode a sealing layer that covers the capacitive element, the sealing layer being of a material that is impermeable to hydrogen; and
defining the dielectric layer and the sealing layer by a single photolithographic defining step, so to concurrently pattern the dielectric layer and seal the capacitive element, the dielectric and sealing layers extending laterally beyond the lower electrode after being defined.

11. The process of claim 10 wherein the step of forming the upper electrode is part of the defining step which includes defining the upper electrode in the single photolithographic defining step to concurrently form the upper electrode, pattern the dielectric layer and seal the capacitive element.

12. The process of claim 10 wherein the dielectric layer is a layer of a ferroelectric material.

13. The process of claim 10 wherein the sealing material layer completely covers the lower and upper electrodes of the capacitive element, the process further comprising selectively etching the sealing layer to produce gaps through which hydrogen can reach the MOS transistor.

14. The process of claim 10, further comprising forming spacers laterally of the capacitive element to laterally seal the dielectric layer along its sides.

15. The process of claim 10 wherein the sealing layer is a layer of a ferroelectric material.

16. The process of claim 10, further comprising connecting the lower electrode to a conduction terminal of the MOS transistor through a contact formed in an opening in the insulating layer, the contact comprising a conductive layer lining the opening.

17. The process of claim 16, further comprising filling the opening with an insulating material positioned interiorly of the conductive layer.

18. The process of claim 10 wherein forming the dielectric layer includes extending the dielectric layer beyond the lower electrode such that the dielectric layer contacts lateral sides of the lower electrode.

19. An integrated memory device, comprising:
a MOS transistor formed on a semiconductor substrate;
an insulating layer positioned on the substrate and MOS transistor;
a capacitive element positioned on the insulating layer, the capacitive element including a conductive lower electrode positioned on the insulating layer, a dielectric layer positioned on the lower electrode and extending laterally of the lower electrode, and a conductive upper electrode positioned on the dielectric layer; and
a sealing layer that covers the capacitive element, the sealing layer being of a material that is impermeable to hydrogen.

20. The memory device of claim 19 wherein the sealing layer, upper electrode, and dielectric layer are coextensive to a position that is lateral of the lower electrode.

21. The memory device of claim 19 wherein the sealing material layer completely covers the lower and upper electrodes of the capacitive element, and has gaps laterally of the capacitive element through which hydrogen can reach the MOS transistor.

22. The memory device of claim 19, further comprising spacers positioned laterally of the capacitive element to seal the dielectric layer along its sides.

23. The memory device of claim 19 wherein the sealing layer includes a layer of a ferroelectric material.

24. The memory device of claim 19, further comprising a contact positioned in the insulating layer and connecting the lower electrode to a conduction terminal of the MOS transistor, the contact comprising an outer metal layer.

25. The memory device of claim 24, wherein the contact further includes an insulating plug positioned interiorly of the metal layer.
